(19) United States
(12) Patent Application Publication
(10) Pub. No.: US 2023/0054810 A1
(43) Pub. Date: Feb. 23, 2023

(54) DISPLAY DEVICE AND METHOD OF MANUFACTURING THE SAME

(71) Applicant: Samsung Display Co., Ltd., Yongin-si (KR)

(72) Inventors: KYUNGHOON CHAE, Asan-si (KR); DAEWOO LEE, Sejong-si (KR); YUNJEONG CHO, Cheonan-si (KR); HYEON DEUK HWANG, Cheonan-si (KR); DOHYUNG RYU, Yongin-si (KR)

(21) Appl. No.: 17/692,660

(22) Filed: Mar. 11, 2022

(30) Foreign Application Priority Data
Aug. 23, 2021 (KR) 10-2021-0111280

(51) Int. Cl. H01L 51/52; H01L 51/56

(52) U.S. Cl. CPC H01L 51/5253; H01L 51/56; H01L 2227/323; H01L 2251/5338; H01L 51/0097

(57) ABSTRACT

A display device includes: a substrate including a display area, a pad area, and a bending area, where the bending area is positioned between the display area and the pad area, is bent from the display area, and is divided into a first area and a second area surrounding the first area; a protection film disposed on the substrate to overlap the display area, the pad area, and the second area, where an opening overlapping the first area is defined in the protection film; and a reinforcing agent disposed in the opening.

This application claims priority to Korean Patent Application No. 10-2021-0111280, filed on Aug. 23, 2021, and all the benefits accruing therefrom under 35 U.S.C. § 119, the content of which in its entirety is herein incorporated by reference.

### BACKGROUND

### 1. Field

Embodiments of the invention relate generally to a display device and a method of manufacturing the display device. More specifically, embodiments of the invention relate to a flexible display device and a method of manufacturing the flexible display device.

### 2. Description of the Related Art

Recently, a display device having a structure in which a substrate is bent has been developed to reduce a dead space in the display device. In such a display device, as the substrate may be bent in a way such that a pad area overlaps a display area, the dead space viewed through a front surface of the display device may be substantially reduced.

### SUMMARY

Embodiments provide a display device with improved durability.

Embodiments provide a method of manufacturing the display device.

An embodiment of a display device includes a substrate including a display area, a pad area, and a bending area, where the bending area is positioned between the display area and the pad area, is bent from the display area, and is divided into a first area and a second area surrounding the first area, a protection film disposed on the substrate to overlap the display area, the pad area, and the second area, where an opening overlapping the first area is defined in the protection film, and a reinforcing agent disposed in the opening.

According to an embodiment, the opening may be defined through the protection film.

According to an embodiment, the opening may not overlap the second area.

According to an embodiment, the reinforcing agent may overlap the first area.

According to an embodiment, the reinforcing agent may not overlap the second area.

According to an embodiment, the display device may further include a display panel disposed on a first surface of the substrate and overlapping the display area and a pad part disposed on the first surface of the substrate and overlapping the pad area. In such an embodiment, the protection film may be disposed on a second surface opposite to the first surface of the substrate.

According to an embodiment, the display device may further include a line connected between the display panel and the pad part, where the line may overlap the first area.

According to an embodiment, the display panel may include a transistor electrically connected to the pad part, a first electrode disposed on the transistor and connected to the transistor, an organic emission layer disposed on the first electrode, a second electrode disposed on the organic emission layer, and an encapsulation layer disposed on the second electrode and including an inorganic layer and an organic layer.

According to an embodiment, the reinforcing agent may have a rectangular shape with rounded corners.

According to an embodiment, the reinforcing agent may be disposed along a curvature of a curved side of the bending area.

According to an embodiment, the reinforcing agent may include a first reinforcing agent and a second reinforcing agent spaced apart from the first reinforcing agent.

According to an embodiment, the reinforcing agent may include a resin.

According to an embodiment, the protection film may include a base layer and an adhesive layer disposed between the substrate and the base layer, and the adhesive layer may adhere the base layer to the substrate.

According to an embodiment, the opening may be defined through the base layer and the adhesive layer.

An embodiment of a method of manufacturing a display device includes preparing a substrate including a display area, a pad area, and a bending area, where the bending area is positioned between the display area and the pad area, is divided into a first area and a second area surrounding the first area, and is bent from the display area, preparing a protection film in which an opening is defined to correspond to the first area of the bending area, adhering the protection film to the display area, the pad area, and the second area of the substrate, where the opening overlaps the first area, and providing a reinforcing agent in the opening.

According to an embodiment, the opening may be formed through the protection film.

According to an embodiment, the opening may not overlap the second area.

According to an embodiment, the reinforcing agent may overlap the first area.

According to an embodiment, the reinforcing agent may not overlap the second area.

According to an embodiment, the reinforcing agent may include a resin.

In embodiments of the invention, a display device may include a protection film and a reinforcing agent. The protection film may be adhered to the rear surface of the substrate, and an opening may be formed through the protection film. The reinforcing agent may be disposed in the opening. In such embodiments, as the reinforcing agent fills the opening, durability of the display device in the bent area may be improved. In such embodiments, the protection film remaining around the opening may serve as a dam to prevent the reinforcing agent from overflowing.

### BRIEF DESCRIPTION OF THE DRAWINGS

The above and other features of the invention will become more apparent by describing in further detail embodiments thereof with reference to the accompanying drawings, in which:

FIG. 1 is a plan view illustrating a display device according to an embodiment;

FIG. 2 is a rear view illustrating the display device of FIG. 1;

FIG. 3 is a cross-sectional view taken along line I-I′ of FIG. 1;

FIG. 4 is a cross-sectional view taken along line II-IF of FIG. 1;

FIG. 5 is a cross-sectional view taken along line of FIG. 2;

FIG. 6 is a cross-sectional view illustrating a pixel structure included in the display device of FIG. 1;

FIG. 7 to FIG. 9 are rear views illustrating an embodiment of a method of manufacturing the display device of FIG. 1;

FIG. 10 to FIG. 13 are rear views illustrating an alternative embodiment of a method of manufacturing the display device of FIG. 1;

FIG. 14 is a rear view illustrating a display device according to an alternative embodiment; and

FIG. 15 is a rear view illustrating a display device according to another alternative embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

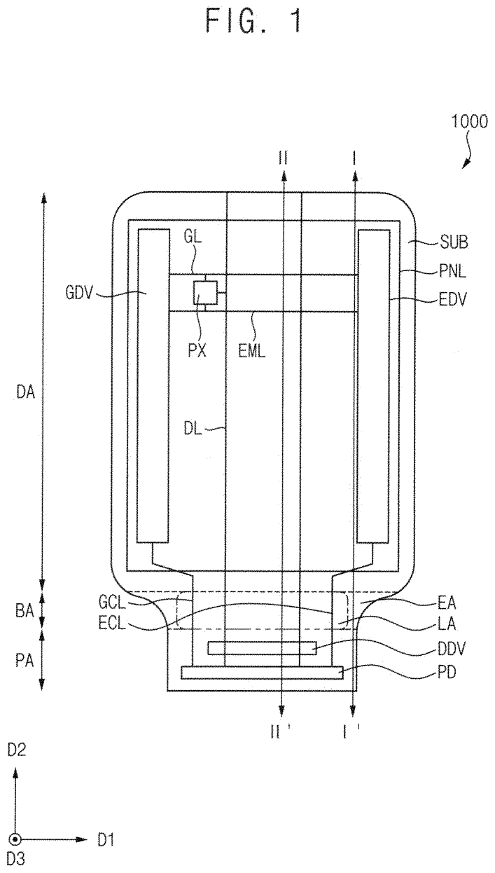

FIG. 1 is a plan view illustrating a display device according to an embodiment.

Referring to FIG. 1, an embodiment of a display device 1000 may be divided into a display area DA, a bending area BA, and a pad area PA. In an embodiment, a substrate SUB of the display device 1000 may be divided into the display area DA, the bending area BA, and the pad area PA. In an embodiment, for example, a display panel PNL may be disposed on a substrate SUB in the display area DA, and an image may be displayed in the display area DA. The display panel PNL may have a rectangular shape including short sides extending in a first direction D1 and long sides extending in a second direction D2. Herein, a third direction D3 may be a direction perpendicular to the first direction D1 and the second direction D2 or a thickness direction of the display panel PNL. The pad area PA may be a contact area with a flexible printed circuit board (“FPCB”), and a pad part PD may be disposed in the pad area PA. The pad part PD may include a plurality of pads, and the pads may receive an electrical signal from an external device.

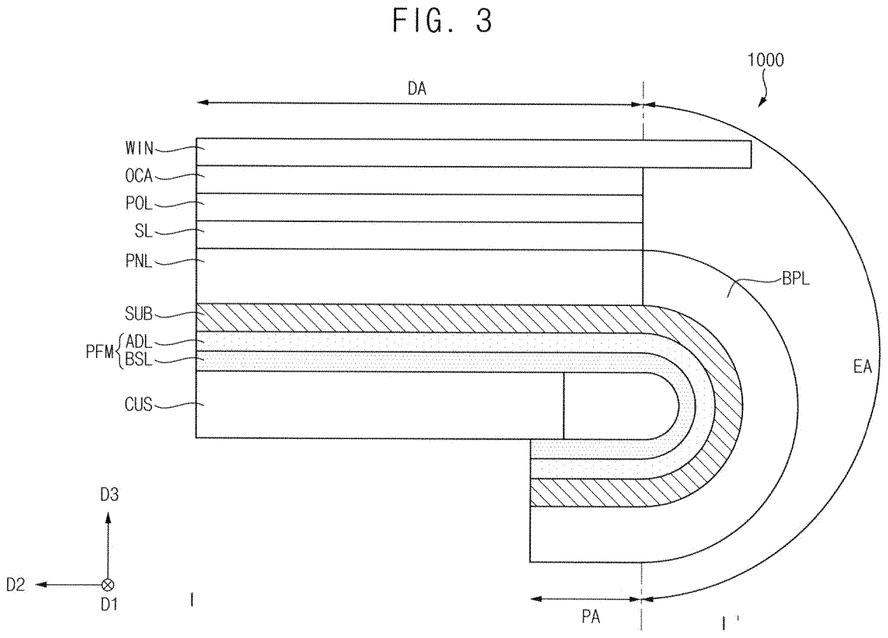

The bending area BA may be positioned between the display area DA and the pad area PA. In an embodiment, for example, as shown in FIG. 3, the bending area BA may be bent. Accordingly, a dead space of the display device 1000 may be reduced. In an embodiment, the bending area BA may be divided into a first area (hereinafter, a line area LA) and a second area (hereinafter, an edge area EA). In an embodiment, for example, the line area LA may be defined as an area overlapping lines (e.g. a gate control line GCL, an emission control line ECL, a data line DL, etc.) connecting the display panel PNL and the pad part PD. In an embodiment, the edge area EA may not overlap the lines. The line area LA may be positioned at a center of the bending area BA, and the edge area EA may be positioned to surround the line area LA.

The display panel PNL may be disposed in the display area DA. The display panel PNL may include a gate driver GDV, an emission driver EDV, and a pixel structure PX.

The gate driver GDV may be connected to the gate control line GCL and a gate line GL. The gate driver GDV may receive a gate control signal through the gate control line GCL. In an embodiment, for example, the gate control signal may include a vertical start signal, a clock signal, and the like. The gate driver GDV may generate a gate signal and may provide the gate signal through the gate line GL. In an embodiment, for example, the gate signal may be a clock signal, and may include a turn-on voltage for turning on the transistor and a turn-off voltage for turning off the transistor.

In an embodiment, the gate driver GDV may be mounted on the display panel PNL or integrated in a peripheral portion of the display panel PNL. In an alternative embodiment, the gate driver GDV may be implemented with or defined by one or more integrated circuits.

The emission driver EDV may be connected to the emission control line ECL and an emission driving line EML. The emission driver EDV may receive an emission control signal through the emission control line ECL. In an embodiment, for example, the emission control signal may include a vertical start signal, a clock signal, and the like. The emission driver EDV may generate an emission driving signal and may provide the emission driving signal through the emission driving line EML. In an embodiment, for example, the emission driving signal may be a clock signal, and may include a turn-on voltage for turning on the transistor and a turn-off voltage for turning off the transistor.

In an embodiment, the emission driver EDV may be mounted on the display panel PNL or integrated in a peripheral portion of the display panel PNL. In an alternative embodiment, the emission driver EDV may be implemented with or defined by one or more integrated circuits.

The data driver DDV may be connected to the pad part PD and the data line DL. The data driver DDV may receive image data and a data control signal from the pad part PD. The data driver DDV may generate a data voltage and may provide the data voltage through the data line DL.

In an embodiment, the data driver DDV may be implemented with or defined by one or more integrated circuits. In an alternative embodiment, the data driver DDV may be mounted on the display panel PNL or integrated in a peripheral portion of the display panel PNL.

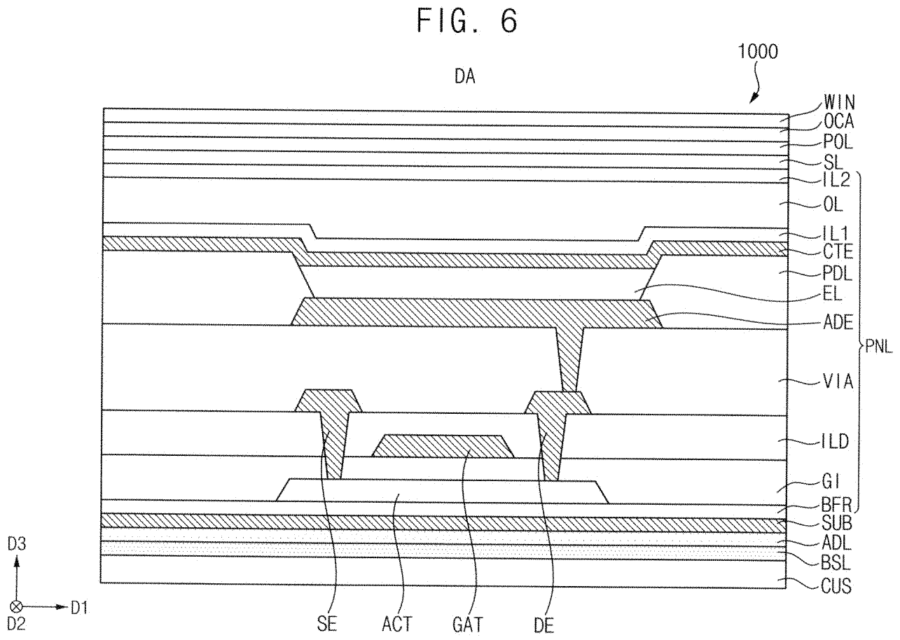

The pixel structure PX may be connected to the gate line GL, the emission driving line EML, and the data line DL. The pixel structure PX may generate light based on the gate signal, the emission driving signal, and the data voltage. The structure of the pixel structure PX will be described with reference to FIG. 6.

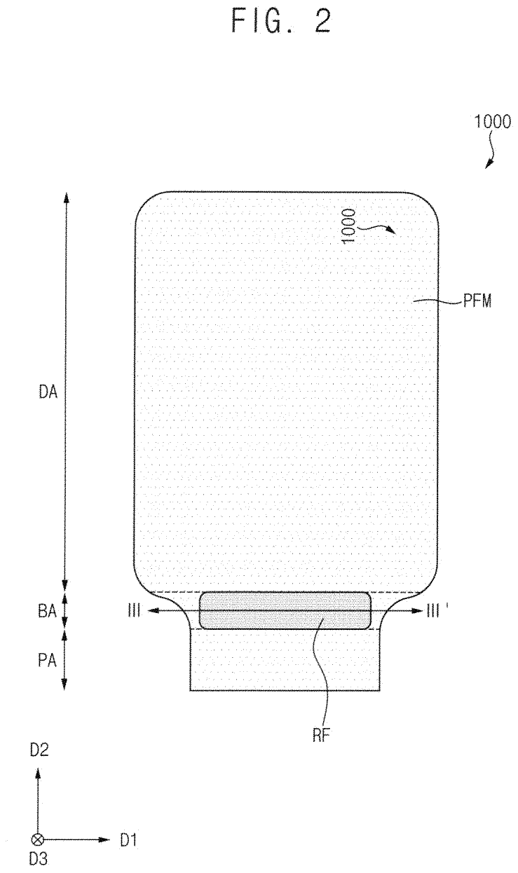

FIG. 2 is a rear view illustrating the display device of FIG. 1.

Referring to FIG. 2, an embodiment of the display device 1000 may include a protection film PFM and a reinforcing agent RF. In an embodiment, for example, the display panel PNL and the pad part PD may be disposed on a first surface (e.g., a front surface) of the substrate SUB, and the protection film PFM and the reinforcing agent RF may be disposed on a second surface (e.g., a rear surface) opposite to the first surface of the substrate SUB.

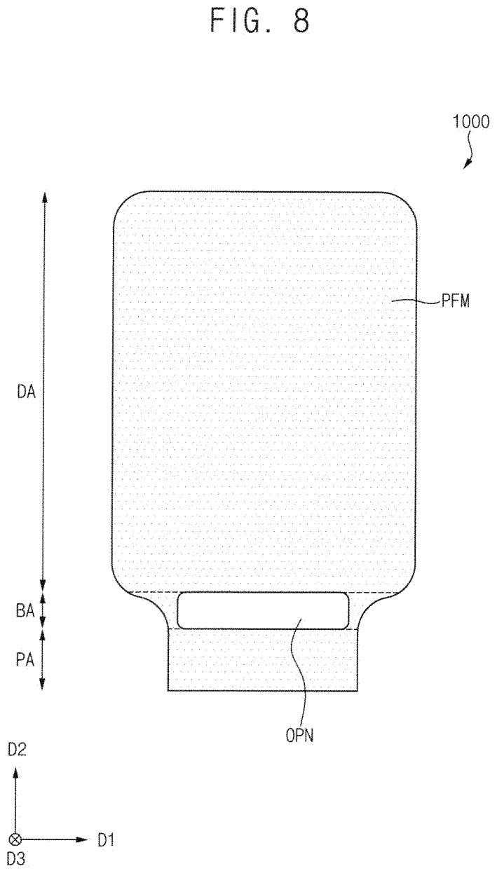

In an embodiment, the protection film PFM may be integrally formed to overlap the display area DA, the pad area PA, and the edge area EA. An opening (e.g., an opening OPN in FIG. 8) overlapping the line area LA may be defined or formed in the protection film PFM, and the reinforcing agent RF may be disposed in the opening OPN. Accordingly, the reinforcing agent RF may overlap the lines. The structures of the protection film PFM and the reinforcing agent RF will be described in detail with reference to FIGS. 3 to 5.

The protection film PFM may support the substrate SUB so that the bent substrate SUB is not damaged, and may protect the substrate SUB so that impurities do not penetrate into the substrate SUB. The reinforcing agent RF may protect the bent lines from external impact so that the bent lines are not damaged.

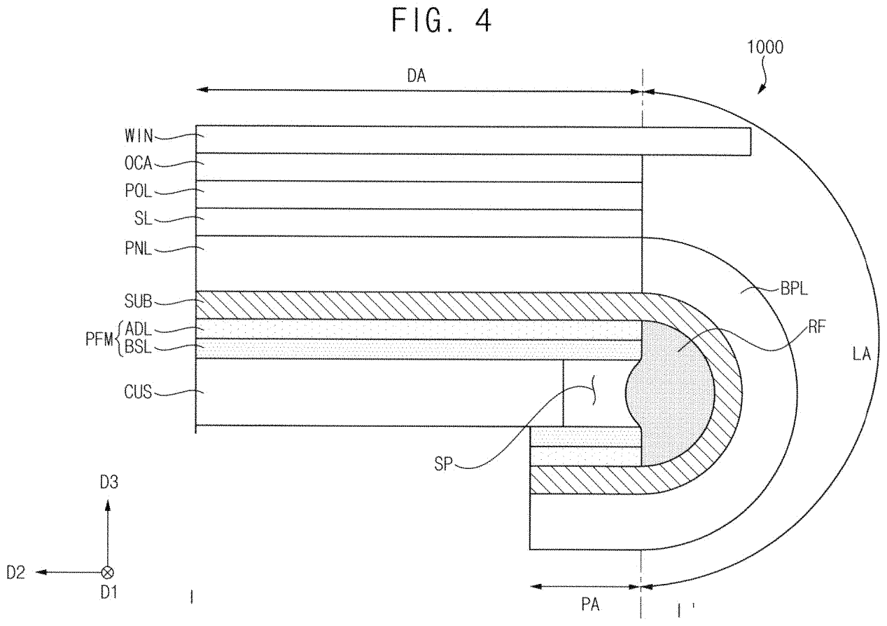

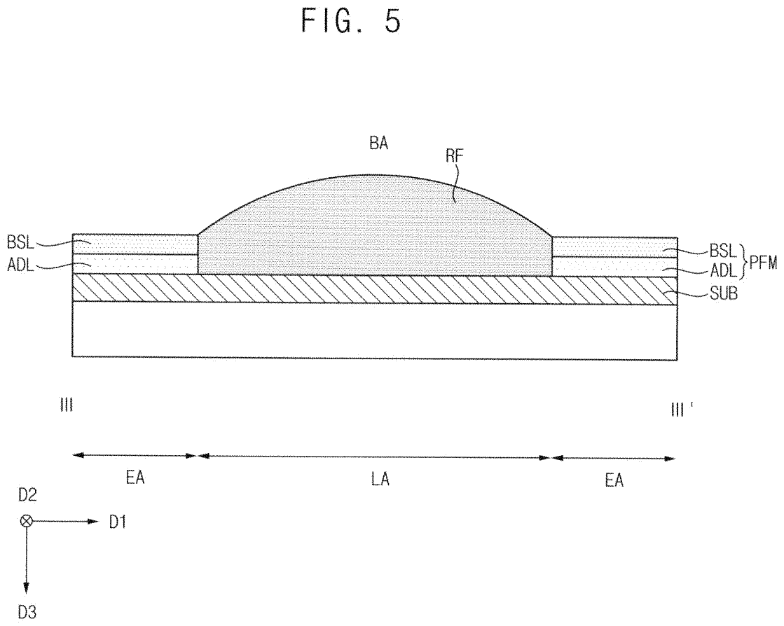

FIG. 3 is a cross-sectional view taken along line I-I′ of FIG. 1. FIG. 4 is a cross-sectional view taken along line II-IF of FIG. 1. FIG. 5 is a cross-sectional view taken along line of FIG. 2.

Referring to FIGS. 3 and 4, an embodiment of the display device 1000 may be bent in the bending area BA. The display device 1000 may include the substrate SUB, the display panel PNL, a sensing layer SL, an anti-reflection layer POL, a window adhesive layer OCA, a window WIN, a bending protection layer BPL, a protection film PFM, a cushion layer CUS, and a reinforcing agent RF.

The substrate SUB may include or be formed of a transparent or opaque material. In an embodiment, for example, the substrate SUB may include or be formed of glass, quartz, plastic, or the like. In an embodiment, plastics that may be included in the substrate SUB may be polyethylene terephthalate (“PET”), polyimide (“P1”), polyethersulfone (“PS”), polyacrylate (“PAR”), polyetherimide (“PEI”), polyethylene naphthalate (“PEN”), polyphenylene sulfide (“PPS”), polyarylate, polycarbonate (“PC”), polyarylene ether sulfone, or the like, for example. In such an embodiment, the substrate SUB may include a plurality of polyimide layers and barrier layers disposed between the polyimide layers.

The display panel PNL may be disposed on the substrate SUB. The structure of the display panel PNL will be described later in detail with reference to FIG. 6.

The sensing layer SL may be disposed on the display panel PNL. The sensing layer SL may include a plurality of sensing electrodes, and may sense a user's touch.

The anti-reflection layer POL may be disposed on the sensing layer SL. The anti-reflection layer POL may transmit light having a predetermined vibration direction. Accordingly, the anti-reflection layer POL may prevent reflection of external light to improve display quality of the display device 1000.

The window adhesive layer OCA may be disposed on the anti-reflection layer POL. The window adhesive layer OCA may adhere the window WIN to the anti-reflection layer POL. In an embodiment, the window adhesive layer OCA may include an optical clear adhesive. In an alternative embodiment, the window adhesive layer OCA may include an optical clear resin, a pressure sensitive adhesive, or the like.

The bending protection layer BPL may extend from the display panel PNL and may cover the substrate SUB overlapping the bending area BA. The bending protection layer BPL may prevent stress from being concentrated on the substrate SUB.

In an embodiment, as shown in FIG. 3, the protection film PFM may overlap the edge area EA. The protection film PFM may include a base layer BSL and an adhesive layer ADL. In an embodiment, for example, the base layer BSL may support the substrate SUB. The adhesive layer ADL may be disposed between the substrate SUB and the base layer BSL, and may adhere the base layer BSL to the substrate SUB.

In an embodiment, the base layer BSL may include glass or plastic. In an embodiment, the material that included in the base layer BSL may be ultra-thin tempered glass (“UTG”), polyethylene terephthalate (“PET”), polyimide (“PI”), polyethersulfone (“PS”), polyacrylate (“PAR”), polyetherimide (“PEI”), polyethylene naphthalate (“PEN”), polyphenylene sulfide (“PPS”), polyarylate, polycarbonate (“PC”), polyarylene ether sulfone, or the like, for example.

In an embodiment, the adhesive layer ADL may include an optically transparent adhesive, an optically transparent adhesive resin, a pressure-sensitive adhesive, or the like.

The cushion layer CUS may include or be formed of a material having elasticity. In an embodiment, the cushion layer CUS may be disposed in an area where the protection film PFM faces each other as the protection film PFM is bent. In an embodiment, for example, the cushion layer CUS may be disposed in a space where the protection film PFM is spaced apart. The cushion layer CUS may absorb an impact to protect the display panel PNL.

In an embodiment, as shown in FIG. 4, the reinforcing agent RF may overlap the line area LA. In an embodiment, for example, the opening OPN may be defined through the protection film PFM overlapping the line area LA and may expose the substrate SUB of the line area LA. In such an embodiment, the reinforcing agent RF may be disposed in the opening OPN to fill the opening OPN. Accordingly, the reinforcing agent RF may contact the protection film PFM and the substrate SUB. In such an embodiment, as the reinforcing agent RF fills the opening OPN, durability of the substrate SUB overlapping the line area LA and the lines may be improved. In such an embodiment, the reinforcing agent RF may protect the substrate SUB and the lines from an external impact applied to the line area LA. In such an embodiment, the reinforcing agent RF may fill a part of a space SP defined by the cushion layer CUS. In an embodiment, for example, the reinforcing agent RF may not contact the cushion layer CUS and may be formed in a portion of the space SP. In an alternative embodiment, the reinforcing agent RF may fill the entire space SP. In an embodiment, for example, the reinforcing arm RF may be disposed in the entire space SP to contact the cushion layer CUS. In an embodiment, the reinforcing agent RF may include or be formed of a resin. In an embodiment, for example, the reinforcing agent RF may be formed by injecting a liquid or paste-type material into the opening OPN and curing the injected material. However, the invention is not limited thereto, and alternatively, the reinforcing agent RF may include be formed of any organic material, any inorganic material, any metal material, etc. capable of protecting the substrate SUB and the lines. In addition, such materials may be used alone or in combination with each other.

Referring to FIG. 5, the protection film PFM may overlap the edge area EA. The opening OPN may be defined or formed in the protection film PFM, and the opening OPN may overlap the line area LA and not overlap the edge area EA. The reinforcing agent RF may be disposed or formed in the opening OPN. In such an embodiment, the reinforcing agent RF may overlap the line area LA and may not overlap the edge area EA. The protection film PFM formed on the edge area EA may improve durability of the edge area EA. In such an embodiment, a portion of the protection film PFM disposed on the edge area EA may serve as a dam to prevent the reinforcing agent RF from overflowing to the outside of the edge area EA. In such an embodiment, as described above, the reinforcing agent RF may improve durability of the line area LA.

However, the shape in which the protection film PFM is disposed is not limited thereto. In an embodiment, for example, the reinforcing agent RF may be disposed on the opening OPN and the base layer BSL adjacent to the opening OPN. In such an embodiment, the reinforcing agent RF may overflow from the opening OPN. In such an embodiment, the reinforcing agent RF may overlap the line area LA and a portion of the edge area EA.

FIG. 6 is a cross-sectional view illustrating a pixel structure included in the display device of FIG. 1.

Referring to FIG. 6, an embodiment of the display panel PNL may include a buffer layer BFR, an active pattern ACT, a gate insulating layer GI, a gate electrode GAT, an interlayer insulating layer ILD, a source electrode SE, a drain electrode DE, a via insulating layer VIA, a first electrode ADE, a pixel defining layer PDL, an organic emission layer EL, a second electrode CTE, a first inorganic layer IL1, an organic layer OL, and a second inorganic layer IL2.

The buffer layer BFR may be disposed on the substrate SUB. In an embodiment, the buffer layer BFR may include an inorganic material. In an embodiment, the material included in the buffer layer BFR may be silicon oxide, silicon nitride, silicon oxynitride, or the like, for example. These may be used alone or in combination with each other.

The buffer layer BFR may prevent diffusion of metal atoms or impurities from the substrate SUB into the active pattern ACT. In such an embodiment, the buffer layer BFR may control a heat supply rate during a crystallization process for forming the active pattern ACT.

The active pattern ACT may be disposed on the buffer layer BFR and may overlap the display area DA. In an embodiment, the active pattern ACT may be a silicon semiconductor, an oxide semiconductor, or the like. In an embodiment, the material included in the active pattern ACT may be amorphous silicon, polycrystalline silicon, or metal oxide, for example. These may be used alone or in combination with each other.

The gate insulating layer GI may cover the active pattern ACT and may be disposed on the buffer layer BFR. In an embodiment, the gate insulating layer GI may include an inorganic insulating material. In an embodiment, the material included in the gate insulating layer GI may be silicon oxide, silicon nitride, silicon oxynitride, or the like, for example. These may be used alone or in combination with each other.

The gate electrode GAT may be disposed on the gate insulating layer GI and may overlap the active pattern ACT. In an embodiment, the gate electrode GAT may include a metal, an alloy, a conductive metal oxide, a transparent conductive material, or the like. In an embodiment, the material included in the gate electrode GAT may be silver (Ag), an alloy containing silver, molybdenum (Mo), an alloy containing molybdenum, aluminum (Al), an alloy containing aluminum, tantalum (Ta), platinum (Pt), scandium (Sc), indium tin oxide (“ITO”), indium zinc oxide (“IZO”), or the like, for example. These may be used alone or in combination with each other.

The interlayer insulating layer ILD may cover the gate electrode GAT and may be disposed on the gate insulating layer GI. In an embodiment, the interlayer insulating layer ILD may include an inorganic insulating material. In an embodiment, the material included in the interlayer insulating layer ILD may be silicon oxide, silicon nitride, silicon oxynitride, or the like, for example. These may be used alone or in combination with each other.

The source electrode SE and the drain electrode DE may be disposed on the interlayer insulating layer ILD and may contact the active pattern ACT. In an embodiment, the source electrode SE and the drain electrode DE may include a metal, an alloy, a conductive metal oxide, a transparent conductive material, or the like. These may be used alone or in combination with each other. In an embodiment, for example, the source electrode SE and the drain electrode DE may have a Ti/Al/Ti structure.

The via insulating layer VIA may cover the source electrode SE and the drain electrode DE, and may be disposed on the interlayer insulating layer ILD. In an embodiment, the via insulating layer VIA may include an organic insulating material. In an embodiment, the material included in the via insulating layer VIA may be photoresist, polyacrylic resin, polyimide resin, acrylic resin, or the like, for example. These may be used alone or in combination with each other.

The first electrode ADE may be disposed on the via insulating layer VIA and may contact the drain electrode DE. In an embodiment, the first electrode ADE may include a metal, an alloy, a conductive metal oxide, a transparent conductive material, or the like. In an embodiment, the material included in the first electrode ADE may be silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), ITO, IZO, or the like, for example. These may be used alone or in combination with each other. In an embodiment, the first electrode ADE may have an ITO/Ag/ITO structure.

The pixel defining layer PDL may be disposed on the first electrode ADE. In an embodiment, the pixel defining layer PDL may include an organic insulating material. A pixel opening exposing an upper surface of the first electrode ADE may be defined or formed in the pixel defining layer PDL.

The organic emission layer EL may be disposed in the pixel opening. The organic emission layer EL may generate light based on a driving current. In an embodiment, for example, the organic emission layer EL may include an organic light emitting material.

The second electrode CTE may be disposed on the organic emission layer EL. In an embodiment, the second electrode CTE may include a metal, an alloy, a conductive metal oxide, a transparent conductive material, or the like. The first electrode ADE, the organic emission layer EL, and the second electrode CTE may constitute an organic light emitting diode.

In embodiments, the light emitting diode included in the display device 1000 may not be limited to the organic light emitting diode. In an alternative embodiment, for example, the light emitting diode may be a light emitting diode including at least one selected from a micro light emitting diode (“micro-LED”), a nano light emitting diode (“nano-LED”), a quantum dot (“QD”), and a quantum rod (“QR”).

An encapsulation layer may be disposed on the second electrode CTE. The encapsulation layer may include an insulating material. In an embodiment, for example, the encapsulation layer may have a structure in which at least one inorganic layer and at least one organic layer are alternately stacked one on another. In an embodiment, for example, the encapsulation layer may include the first inorganic layer ILL the organic layer OL disposed on the first inorganic layer ILL and the second inorganic layer IL2 disposed on the organic layer OL. The encapsulation layer may prevent foreign matter from penetrating into the organic emission layer EL.

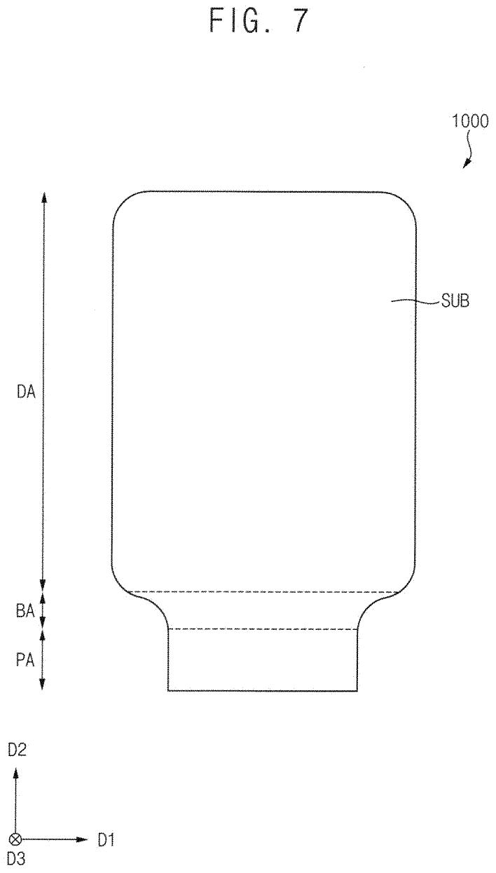

FIG. 7 to FIG. 9 are rear views illustrating an embodiment of a method of manufacturing the display device of FIG. 1.

Referring to FIG. 7, the substrate SUB may be prepared. The rear surface of the substrate SUB is shown in FIG. 7, and the display panel PNL, the pad part PD, and the lines may be formed or disposed on the front surface of the substrate SUB.

Referring to FIG. 8, the protection film PFM having the opening OPN may be provided or formed on the rear surface of the substrate SUB. In an embodiment, for example, the protection film PFM in which the opening OPN is formed may be separately prepared, and the protection film PFM may be adhered to the rear surface of the substrate SUB. In an embodiment, as described above, the opening OPN may be formed in an area into which the reinforcing agent RF is to be injected, and in such an embodiment, the opening OPN may overlap the line region LA.

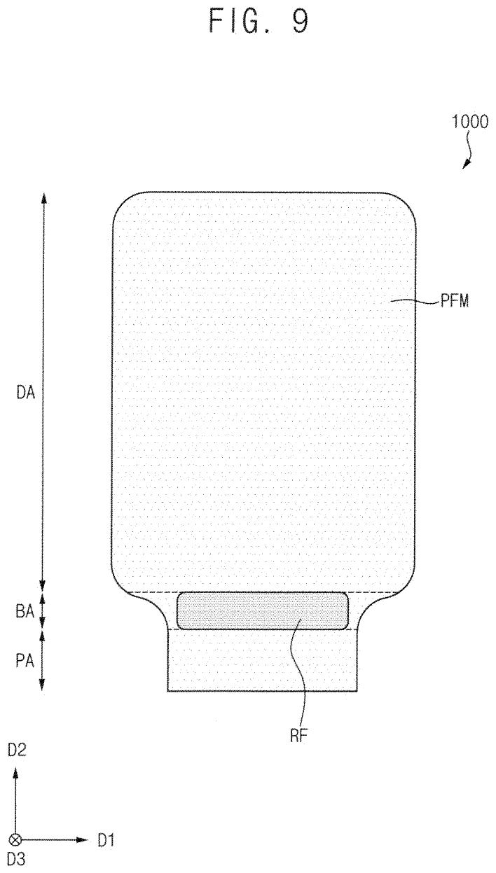

Referring to FIG. 9, the reinforcing agent RF may be provided or formed in the opening OPN. In an embodiment, the reinforcing agent RF may be formed by injecting a liquid or paste-type resin and curing it with ultraviolet rays (or heat). As the opening OPN is formed through the protection film PFM, the protection film PFM overlapping the edge area EA may serve as a dam. Accordingly, the reinforcing agent RF may not overflow into the edge area EA.

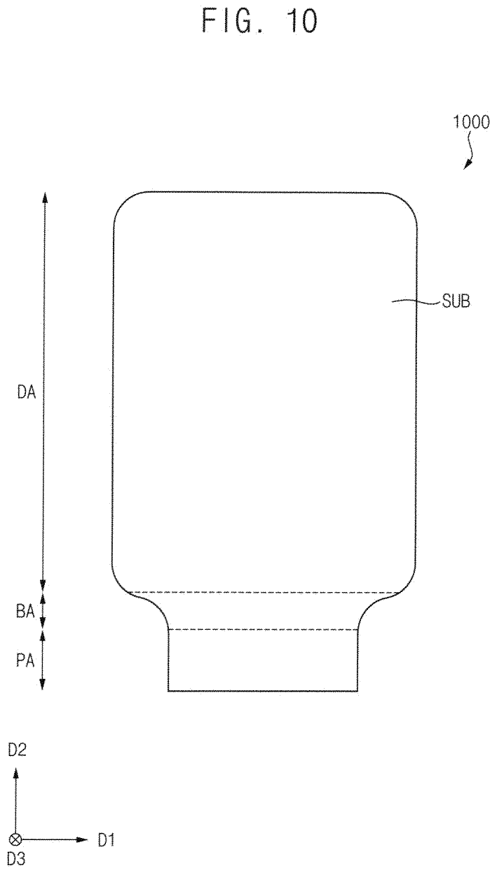

FIG. 10 to FIG. 13 are rear views illustrating an alternative embodiment of a method of manufacturing the display device of FIG. 1.

Referring to FIG. 10, the substrate SUB may be prepared. The substrate SUB may be substantially the same as the substrate SUB described above with reference to FIG. 7.

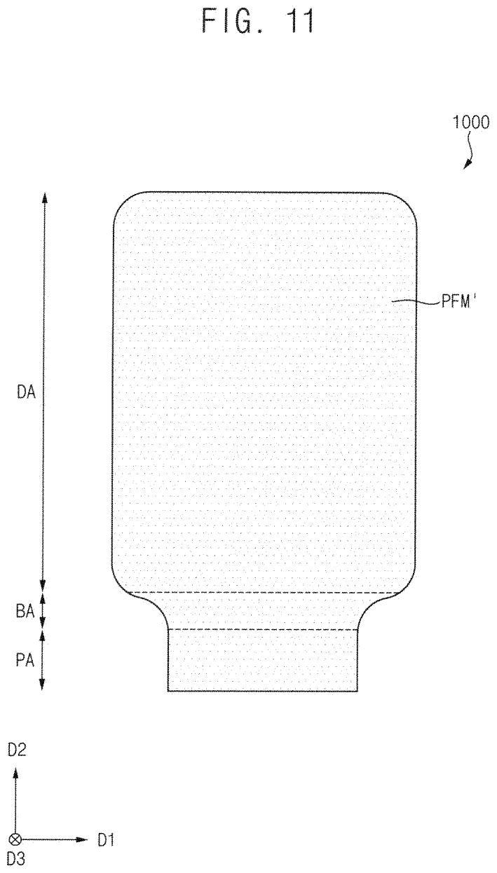

Referring to FIG. 11, a preliminary protection film PFM′ may be provided or formed on the rear surface of the substrate SUB. In an embodiment, for example, the preliminary protection film PFM′ may be a protection film in which the opening OPN is not formed.

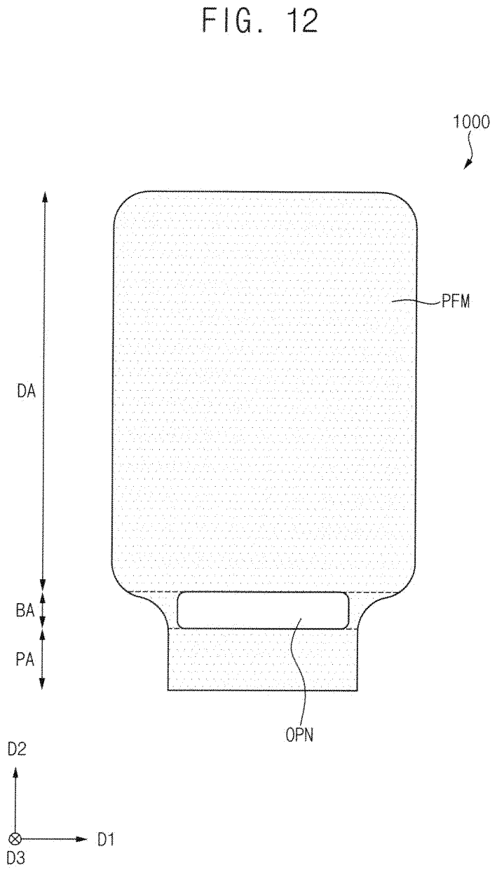

Referring to FIG. 12, the opening OPN may be formed through the preliminary protection film PFM′. In an embodiment, the opening OPN may be formed through a laser irradiation process. However, the present invention is not limited thereto, and the process of forming the opening OPN may be appropriately selected as desired. In an embodiment, for example, the opening OPN may be formed through a thermoforming process, a polishing process, a cutting process, or the like. In an embodiment, the opening OPN may be formed using a heat block. In an embodiment, for example, the opening OPN may be formed by removing portions of the preliminary protection film PFM′ in contact with the heat block.

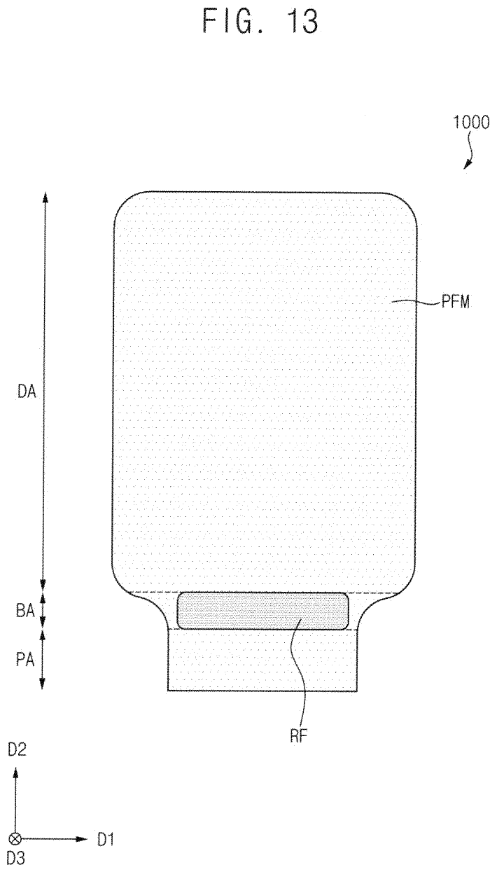

Referring to FIG. 13, the reinforcing agent RF may be provided or formed in the opening OPN. However, the reinforcing agent RF may be substantially the same as the reinforcing agent RF described above with reference to FIG. 9.

However, embodiments of the method of manufacturing the display device 1000 is not limited to those described above. In an alternative embodiment, for example, the protection film may be attached before or after the substrate SUB is cut from a mother substrate. In an alternative embodiment, the opening OPN may be formed before or after being cut in the mother substrate.

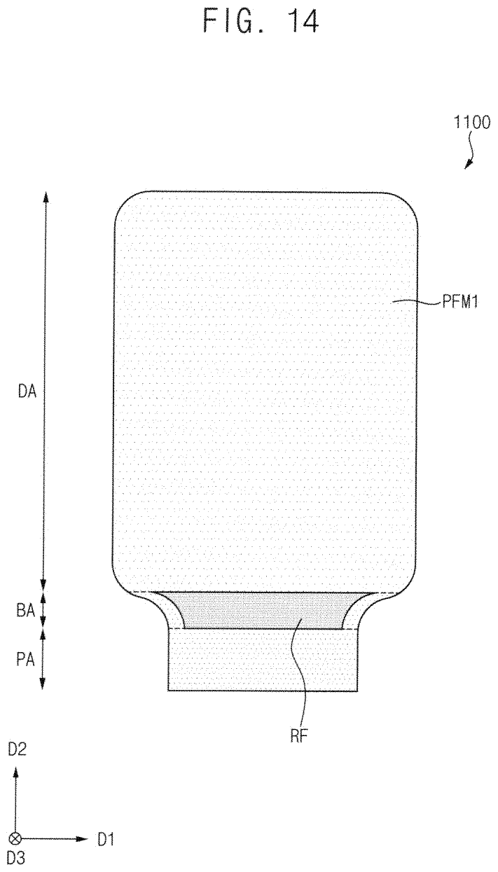

FIG. 14 is a rear view illustrating a display device according to an alternative embodiment.

An embodiment of a display device 1100 shown in FIG. 14 may be substantially the same as the embodiment of the display device 1000 described above with reference to FIG. 2, except for a protection film PFM1 and a reinforcing agent RF. The same or like elements shown in FIG. 14 have been labeled with the same reference characters as used above to describe the embodiment of the display device 1000 in FIG. 2, and any repetitive detailed description thereof will hereinafter be omitted or simplified.

In an embodiment, as shown in FIG. 14, the display device 1100 may include the protection film PFM1 and the reinforcing agent RF. An opening may be defined or formed in the protection film PFM1. The opening may be formed along a curvature of a curved side of the bending area BA. The reinforcing agent RF may be disposed in the opening.

Accordingly, the reinforcing agent RF may be disposed along the curvature of the curved side.

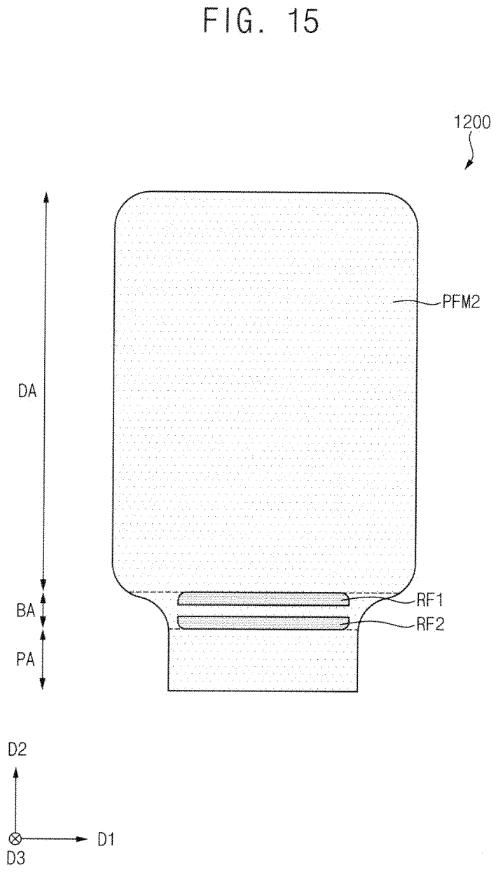

FIG. 15 is a rear view illustrating a display device according to another alternative embodiment.

An embodiment of a display device 1200 shown in FIG. 15 may be substantially the same as the embodiment of the display device 1000 described above with reference to FIG. 2, except for a protection film PFM2 and a reinforcing agent RF. The same or like elements shown in FIG. 15 have been labeled with the same reference characters as used above to describe the embodiment of the display device 1000 in FIG. 2, and any repetitive detailed description thereof will hereinafter be omitted or simplified.

In an embodiment, as shown in FIG. 15, the display device 1200 may include the protection film PFM2 and the reinforcing agent RF. A first opening and a second opening may be formed or defined in the protection film PFM2. The first and second openings may be disposed to be spaced apart from each other. The reinforcing agent RF may include a first reinforcing agent RF1 and a second reinforcing agent RF2. The first reinforcing agent RF1 may be disposed in the first opening, and the second reinforcing agent RF2 may be disposed in the second opening. Accordingly, the first reinforcing agent RF1 and the second reinforcing agent RF2 may be spaced apart from each other.

In embodiments of the invention, as shown in FIGS. 2, 14 and 15, the openings defined in the protection films PFM, PFM1, or PFM2 may be appropriately or variously defined or formed as desired. In an embodiment, for example, the shape and number of the openings may be determined in based on the material of the protection film PFM, PFM1, or PFM2, a thickness of the protection film PFM, PFM1, or PFM2, a component of the reinforcing agent RF, a degree of bending of the substrate SUB, etc.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including a display area, a pad area, and a bending area, wherein the bending area is positioned between the display area and the pad area, is bent from the display area, and is divided into a first area and a second area surrounding the first area;
a protection film disposed on the substrate to overlap the display area, the pad area, and the second area, wherein an opening overlapping the first area is defined in the protection film; and
a reinforcing agent disposed in the opening.

2. The display device of claim 1, wherein the opening is defined through the protection film.

3. The display device of claim 1, wherein the opening does not overlap the second area.

4. The display device of claim 1, wherein the reinforcing agent overlaps the first area.

5. The display device of claim 1, wherein the reinforcing agent does not overlap the second area.

6. The display device of claim 1, further comprising:
a display panel disposed on a first surface of the substrate and overlapping the display area; and
a pad part disposed on the first surface of the substrate and overlapping the pad area, and
wherein the protection film is disposed on a second surface of the substrate opposite to the first surface of the substrate.

7. The display device of claim 6, further comprising:
a line connected between the display panel and the pad part, wherein the line overlaps the first area.

8. The display device of claim 6, wherein the display panel includes:
a transistor electrically connected to the pad part;
a first electrode disposed on the transistor and connected to the transistor;
an organic emission layer disposed on the first electrode;
a second electrode disposed on the organic emission layer; and
an encapsulation layer disposed on the second electrode and including an inorganic layer and an organic layer.

9. The display device of claim 1, wherein the reinforcing agent has a rectangular shape with rounded corners.

10. The display device of claim 1, wherein the reinforcing agent is disposed along a curvature of a curved side of the bending area.

11. The display device of claim 1, wherein the reinforcing agent includes a first reinforcing agent and a second reinforcing agent spaced apart from the first reinforcing agent.

12. The display device of claim 1, wherein the reinforcing agent comprises a resin.

13. The display device of claim 1, wherein the protection film includes:
a base layer; and
an adhesive layer disposed between the substrate and the base layer,
wherein the adhesive layer adheres the base layer to the substrate.

14. The display device of claim 13, wherein the opening is defined through the base layer and the adhesive layer.

15. A method of manufacturing a display device, the method comprising:
preparing a substrate including a display area, a pad area, and a bending area, wherein the bending area is positioned between the display area and the pad area, is divided into a first area and a second area surrounding the first area, and is bent from the display area;
preparing a protection film in which an opening is defined to correspond to the first area of the bending area;
adhering the protection film to the display area, the pad area, and the second area of the substrate, wherein the opening overlaps the first area; and
providing a reinforcing agent in the opening.

16. The method of claim 15, wherein the opening is formed through the protection film.

17. The method of claim 15, wherein the opening does not overlap the second area.

18. The method of claim 15, wherein the reinforcing agent overlaps the first area.

19. The method of claim 15, wherein the reinforcing agent does not overlap the second area.

20. The method of claim 15, wherein the reinforcing agent comprises a resin.
